(19) United States
(12) Patent Application Publication
(10) Pub. No.: US 2012/0279762 A1
(43) Pub. Date: Nov. 8, 2012

(54) COMPOSITION FOR FORMING STRETCHABLE CONDUCTIVE PATTERN, METHOD OF PRODUCING THE STRETCHABLE CONDUCTIVE PATTERN USING THE COMPOSITION, AND ELECTRONIC DEVICE INCLUDING STRETCHABLE CONDUCTIVE ELECTRODE

(75) Inventors: Jae-hyun HUR, Yongin-si (KR); Jong-jin PARK, Yongin-si (KR); Kyu-hyun IM, Yongin-si (KR); Un-yong JEONG, Seoul (KR); Min-woo PARK, Seoul (KR); Dong-choon HYUN, Seoul (KR)

(73) Assignees: INDUSTRY-ACADEMIC COOPERATION FOUNDATION, YONSEI UNIVERSITY, Seoul (KR); SAMSUNG ELECTRONICS CO., LTD., Suwon-si (KR)

(21) Appl. No.: 13/458,139

(22) Filed: Apr. 27, 2012

(30) Foreign Application Priority Data
May 3, 2011 (KR) 10-2011-0042115
Jun. 24, 2011 (KR) 10-2011-0061805

(51) Int. Cl. H05K 1/00; B05D 5/12; B05D 3/10; B05D 3/02; B32B 37/14; B32B 3/16; H01B 1/12; B05D 3/06; B82Y 99/00; B82Y 30/00; B82Y 40/00

(52) U.S. Cl. 174/254; 252/519.21; 427/58; 427/510; 156/275.5; 428/208; 977/890; 977/773; 977/932

(57) ABSTRACT

A method of forming a stretchable conductive pattern includes forming a base substrate; forming a plurality of non-linear trench lines that include peaks and valleys arranged at constant intervals in the base substrate; forming a polymer-metal precursor mixture pattern by filling the trench lines with a mixture of the polymer-metal precursor; converting the polymer-metal precursor mixture of the polymer-metal precursor mixture pattern into a polymer gel/metal nano-particle complex to form a polymer gel/metal nano-particle complex pattern; and primarily transferring the polymer gel/metal nano-particle complex pattern in the base substrate onto an acceptor base substrate.

### CROSS-REFERENCE TO RELATED APPLICATIONS

This application claims the benefit of Korean Patent Application Nos. 10-2011-0042115, filed on May 3, 2011 and 10-2011-0061805, filed on Jun. 24, 2011, in the Korean Intellectual Property Office, the disclosures of which are incorporated herein in their entirety by reference.

### BACKGROUND

1. Field

The present disclosure relates to compositions for forming a stretchable conductive pattern, methods of forming the stretchable conductive pattern using the compositions, and electronic devices including a stretchable conductive electrode.

2. Description of the Related Art

In recent years, demands for flexible electronic devices which may overcome limitations of conventional electronic devices formed on hard substrates are also increasing. Electronic devices such as flexible displays, smart clothing, dielectric elastomer actuators (DEA), biocompatible electrodes, and electronic devices used to detect electric signals in a living body need to be flexible and elastic. In regard to electronic devices having flexibility and elasticity, stretchability and conductivity of an electrode are one of basic considerations.

A metal, which has an excellent conductivity, may not be used as a strechable electrode because the metal is hard and stiff. In addition, it is also difficult to form a strechable electrode by using carbon nano-tube or graphene alone.

To form a stretchable electrode, various methods, for example, mixing carbon nano-tube, transparent fluoride polymer, and ionic liquid to make a paste, making a paste of metal particles and a polyacrylate mixture and forming a pattern by using an inkjet method, and forming a metal layer on a wrinkled polydimethylsiloxane (PDMS) substrate to generate elasticity by smoothing the wrinkles out, have been reported. However, according to the above described examples, the material for forming the electrode or the substrate does not have sufficient elasticity, and thus, the conductivity may be degraded sharply or the electrode may be mechanically damaged, for example it may crack, according to the stretch of the substrate.

### SUMMARY

Provided are compositions for forming stretchable conductive patterns, methods of forming stretchable conductive patterns by using the compositions, and electronic devices including stretchable conductive electrode.

Additional aspects will be set forth in part in the description which follows and, in part, will be apparent from the description, or may be learned by practice of the presented embodiments.

According to an exemplary embodiment, a composition for forming a stretchable conductive pattern, includes: a polymer which forms a gel by a photocuring or a thermal curing; a metal precursor; and a solvent.

The polymer may include polyethyleneglycol diacrylate (PEG-DA), polystyrene polyethyleneoxide polystyrene (PS-PEO-PS), or polyoxybutylene polyethyleneoxide (POB-PEO). The weight % (wt %) of the polymer may be about 0.1 to 10 wt % of the total mass of the composition.

The metal precursor may include AgCF₃COOH, AgNO₃, HAuCl₄, CuCl₂, PtCl₂, or PtCl₄. The wt % of the metal precursor may be about 0.1 to 10 wt % of the entire 100 wt % of the composition.

The solvent may include water, ethanol, dimethylformamide, or dimethyl sulfoxide.

The composition may further include a curing initiator. The curing initiator may be, for example, 2,2-dimethoxy-2-phenylacetophenone (DMPA), and the amount of the curing initiator included in the composition of 100 wt % may be about 0.05 to 5 wt %.

According to another exemplary embodiment a method of forming a stretchable conductive pattern, the method includes: forming a base substrate; forming a plurality of wavy trench lines that have peaks and valleys arranged at constant intervals in the base substrate; forming a polymer-metal precursor mixture pattern by filling the trench lines with a mixture of the polymer and metal precursor; converting the polymer-metal precursor mixture of the polymer-metal precursor mixture pattern into a polymer gel/metal nano-particle complex to form a polymer gel/metal nano-particle complex pattern; and primarily transferring the polymer gel/metal nano-particle complex pattern in the base substrate onto an acceptor substrate.

The forming of the substrate may include: providing a first polymer substrate that has elasticity and may be transformed by heat or stretching; and forming a first polymer layer that may be transformed by the heat or the stretching and has a different elastic modulus or a different thermal expansion coefficient from the material forming the first polymer substrate, on the first polymer substrate.

The forming of the plurality of wavy trench lines on the base substrate may include stretching and releasing the base substrate in a first direction and stretching and releasing the base substrate in a second direction that is perpendicular to the first direction.

The plurality of wavy trench lines may be arranged with a constant distance between each of the trench lines. The trench lines may be aligned parallel to each other in a first direction, that is, the peaks of each trench line may be parallel with the peaks of an adjacent trench line, and the valleys of each trench line may be parallel with the valleys of an adjacent trench line.

The forming of the plurality of wavy trench lines in the base substrate may include raising a temperature of the base substrate to about 80 to 100° C. and returning the temperature to room temperature.

The filling of the trench lines with the polymer-metal precursor mixture may include coating a polymer-metal precursor composition including a polymer which forms a gel by a photocuring or a thermal curing, a metal precursor, and a solvent on the base substrate in which the trench lines are formed.

The converting of the polymer-metal precursor mixture into a polymer gel/metal nano-particle complex may include: curing a polymer in the polymer-metal precursor mixture into a gel state; and reducing a metal precursor of the polymer-metal precursor mixture.

The reducing of the metal precursor may include processing the polymer-metal precursor mixture in hydrazine (N₂H₄) or sodium borohydride (NaBH₄).

The curing of the polymer into the gel state may include irradiating UV rays or performing a heat treatment on the polymer-metal precursor mixture.

The transferring of the polymer gel/metal nano-particle complex pattern may include performing a surface treatment on the acceptor substrate so as to obtain a UV-curable surface which can have a cross-linkage with the polymer gel/metal nano-particle complex before the transferring of the polymer gel/metal nano-particle complex pattern.

The transferring of the polymer gel/metal nano-particle complex pattern may include: aligning the base substrate on which the polymer gel/metal nano-particle complex pattern is formed on the acceptor substrate; and adhering the base substrate aligned on the acceptor substrate to the acceptor substrate, and irradiating UV rays on the base substrate to form cross-linkages between the polymer gel/metal nano-particle complex pattern and the acceptor substrate.

The method may include primarily transferring the polymer gel/metal nano-particle complex pattern on the acceptor substrate, and secondarily transferring the polymer gel/metal nano-particle complex pattern on the acceptor substrate, wherein a direction of the polymer gel/metal nano-particle complex pattern transferred primarily is different from a direction of the polymer gel/metal nano-particle complex pattern transferred secondarily.

According to another aspect of the present invention, an electronic device includes: a flexible substrate; and a stretchable electrode formed of a polymer gel/metal nano-particle complex on the flexible substrate and including a plurality of wave lines.

The polymer gel/metal nano-particle complex may include a polymer gel and metal nano-particles forming a percolation network in the polymer gel.

The flexible substrate may be formed of a flexible polymer.

The flexible substrate may include a circuit electrically connected to the stretchable electrode.

The trench lines may be, but not limited to of a wavy form (e.g., wave or S-shaped) or round sawtooth shaped.

### BRIEF DESCRIPTION OF THE DRAWINGS

These and/or other aspects will become apparent and more readily appreciated from the following description of the embodiments, taken in conjunction with the accompanying drawings of which:

FIG. 1 is a flowchart illustrating a method of forming a stretchable conductive pattern according to an embodiment of the present invention;

FIGS. 2A through 2E are cross-sectional views sequentially illustrating the method of forming the stretchable conductive pattern of FIG. 1;

FIG. 3 is a scanning electron microscopy (SEM) photograph showing a polyethyleneglycol diacrylate (PEG-DA)/Ag precursor mixture filled in trench lines on a base material, in which a polystyrene (PS) layer is formed on a polydimethylsiloxane (PDMS) base substrate according to an embodiment of the present invention;

FIG. 4A is a SEM photograph showing a PEG-DA gel/Ag nano-particle complex pattern filled in the trench lines of the base substrate, and FIG. 4B is a transmission electron microscopy (TEM) photograph showing the PEG-DA gel/Ag nano-particle complex pattern of FIG. 4A;

FIGS. 5A and 5B are respectively a TEM photograph and an X-ray diffraction (XRD) pattern showing Ag nano-particles reduced from AgCF₃COOH;

FIG. 6 is an atomic force microscopy (AFM) image showing the PEG-DA gel/Ag nano-particle complex patterns transferred onto an acceptor substrate;

FIG. 7 is a graph showing results of measuring the weight % (wt %) of Ag in the PEG-DA gel/Ag nano-particle complex according to a density of AgCF₃COOH in a mixture solution of PEG-DA polymer and AgCF₃COOH;

FIG. 8 is a graph measuring an electric conductivity of the PEG-DA gel/Ag nano-particle complex according to the wt % of the Ag nano-particles in the PEG-DA gel/Ag nano-particle complex;

FIG. 9 is a graph showing the electric conductivity of the PEG-DA gel/Ag nano-particle complex according to a temperature and a time taken to perform a heat treatment;

FIG. 10 is a graph showing a variation in the electric conductivity of the PEG-DA gel/Ag nano-particle complex which varies depending on a strain of the PDMS that is the acceptor substrate according to a density of the Ag precursor;

FIG. 11 is a graph showing a variation in the electric conductivity of the PEG-DA gel/Ag nano-particle complex pattern caused by the strain of the PDMS that is the acceptor substrate, measured according to the temperature of the heat treatment;

FIG. 12A is a SEM photograph of PEG-DA gel/Ag nano-particle complex patterns formed as irregularly aligned waves;

FIG. 12B is a SEM photograph of PEG-DA gel/Ag nano-particle complex patterns formed as regularly aligned waves;

FIG. 12C is a graph of electric conductivities according to the strain of PDMS in the PEG-DA gel/Ag nano-particle complex patterns of FIGS. 12A and 12B;

FIG. 12D is a graph of electric conductivities according to an stretch cycle of the PEG-DA gel/Al nano-particle complex pattern of FIG. 12A measured at various strain degrees;

FIG. 13A is an optical microscope photograph showing a regular net type conductive pattern that is formed by the regular wave type PEG-DA gel/Ag nano-particle complex patterns extending in a first direction and a second direction perpendicular to each other;

FIG. 13B is a photograph showing the regular net type conductive patterns of FIG. 13A strained in a Y-axis direction by about 40%;

FIG. 13C is a photograph showing the regular net type conductive patterns of FIG. 13A strained simultaneously in an X-axis direction and Y-axis direction by about 40%;

FIG. 13D is a photograph showing connecting states of circuits before and after strain of a stretchable electrode in a bulb circuit using the conductive pattern of FIG. 13A as the stretchable electrode; and

FIG. 13E is a graph of a transmittance of the PDMS on which the net type conductive patterns are formed.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

A composition for forming a stretchable conductive pattern according to an embodiment of the present invention will be described as follows.

The composition for the stretchable conductive pattern includes a polymer forming gel by a photo-curing or a thermal curing, a metal precursor, and a solvent.

The gel-forming polymer may include polyethyleneglycol diacrylate (PEG-DA), polystyrene polyethyleneoxide polystyrene (PS-PEO-PS), or polyoxybutylene polyethyleneoxide (POB-PEO); however, the embodiment of the present invention is not limited thereto. The gel-forming polymer may be used in an amount of 0.1 to 10 weight % (wt %) based on the total mass of the entire composition.

The metal precursor may include AgCF₃COOH, AgNO₃, HAuCl4, CuCl₂, PtCl₂, or PtCl₄; however, the embodiment of the present invention is not limited thereto. The metal precursor may be 0.1 to 10 wt % of the entire composition of 100 wt %.

The solvent may include water, ethanol, dimethylformamide, or dimethyl sulfoxide; however, the embodiment of the present invention is not limited thereto.

On the other hand, the composition may further include a curing initiator. The curing initiator may be, for example, 2,2-dimethoxy-2-phenylacetophenone (DMPA); however, the embodiment of the present invention is not limited thereto. The amount of the curing initiator included in the composition of 100 wt % may be about 0.05 to 5 wt %.

The composition for the stretchable conductive pattern may form the stretchable conductive pattern through reduction of the metal precursor and curing of the polymer after being coated on a base material.

A method of forming the stretchable conductive pattern will be described in detail according to an embodiment of the present invention.

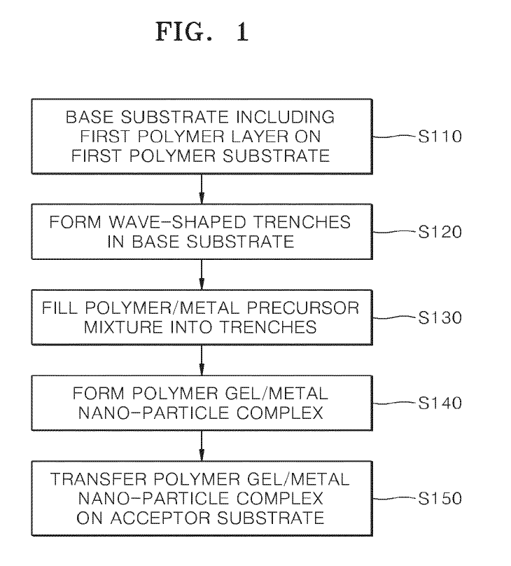

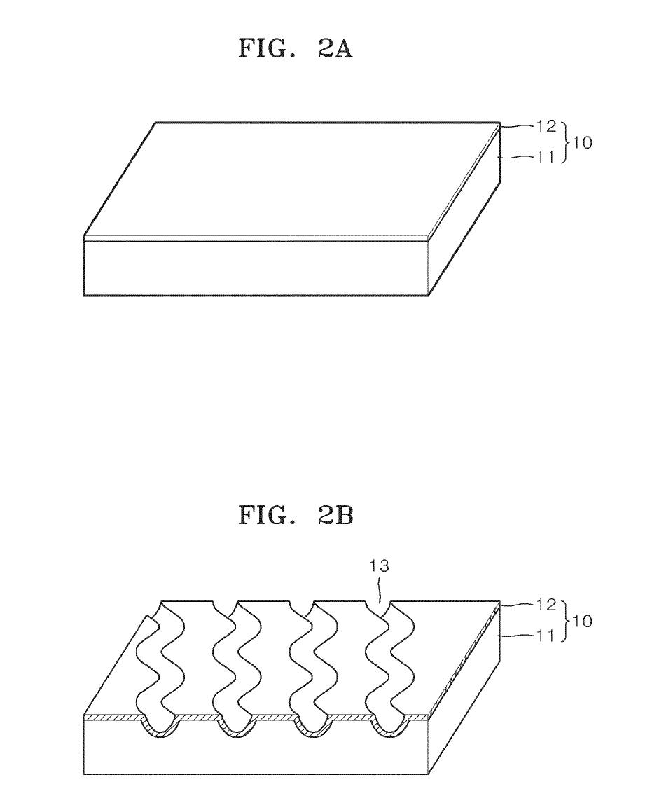

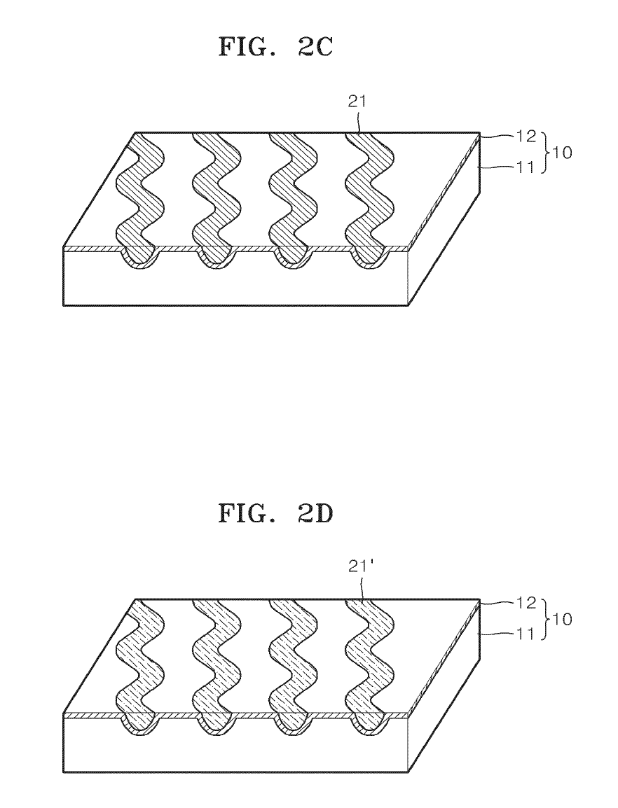

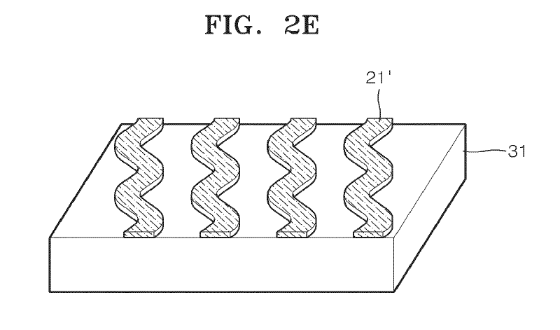

FIG. 1 is a flowchart illustrating a method of forming the stretchable conductive pattern according to an embodiment in which a formation of wave-shaped trenches are explained as an example, and FIGS. 2A through 2E are cross-sectional views illustrating sequences of the method of forming the stretchable conductive pattern of FIG. 1.

Referring to FIGS. 1 and 2A, a base substrate 10 including a first polymer layer 12 formed on a first polymer substrate 11 is prepared (S110).

The first polymer substrate 11 may be formed of a polymer material that have elasticity and may be transformed by heat or stretching. The first polymer substrate 11 may be formed of a thermoplastic polymer such as polydimethylsiloxane (PDMS) based on silicon rubber; however, the embodiment of the present invention is not limited thereto. The first polymer substrate 11 may be formed to a thickness ranging from about 1 μm to 10 mm; however, the embodiment of the present invention is not limited thereto.

The first polymer layer 12 may be formed of a polymer material that may be transformed by heat or stretching, and have an elastic modulus or a thermal expansion coefficient that is different from those of the material forming the first polymer substrate 11. The first polymer layer 12 may be formed on the first polymer substrate 11 by a spin coating method, for example, and may be formed to a thickness of about 50 to 200 nm.

Referring to FIGS. 1 and 2B, a plurality of wavy trench lines 13 are formed in the base substrate 10 (S120). The plurality of wavy trench lines 13 may be formed by extending and then releasing the base substrate 10 in a predetermined direction. Due to a difference between the elastic moduli of the first polymer substrate 11 and the first polymer layer 12, deformation degrees of the first polymer substrate 11 and the first polymer layer 12 are different from each other even when a same force is applied thereto. When a degree of restoration to the original state of the first polymer layer 12 is greater than that of the first polymer substrate 11 through the stretch or when a degree of restoration to the original state of the first polymer substrate 11 is greater than that of the first polymer layer 12 through the stretch, wrinkles are formed on a surface of the first polymer substrate 11, on which the first polymer layer 12 is formed, to form the plurality of wavy trench lines 13.

When the base substrate 10 is stretched and released sequentially in directions perpendicular to each other, the plurality of regular wavy trench lines may be formed at a constant distance. For example, when the base substrate 10 is stretched and released in an X-axis direction and then stretched and released in a Y-axis direction, a trench line having peaks and valleys in the Y-axis direction and extending in the X-axis direction may be formed. Here, the plurality of trench lines may be formed so that the peaks and valleys of neighboring trench lines may align parallel to each other.

In addition, when the base substrate 10 is stretched in two directions perpendicular to each other and simultaneously released, the plurality of wavy trench lines may be formed in a way that they are irregularly aligned. For example, when the base substrate 10 is stretched in the X-axis direction and the Y-axis direction and released simultaneously in the X-axis and Y-axis directions, the base substrate 10 is extended in the irregular directions, and thus, the trench lines having irregular wave shapes may be formed.

Distances between the trench lines 13, depths of the trench lines 13, and sizes or heights of the peaks and valleys in the trench lines 13 may be adjusted according to the stretching direction and the stretching degree of the base substrate 10.

On the other hand, the trench lines 13 may be formed in the base substrate 10 by raising a temperature of the base substrate 10 and then decreasing the temperature again to room temperature, induced by different degree of deformations of the first polymer substrate 11 and the first polymer layer 12 due to the different thermal expansion coefficients. For example, the temperature of the base substrate 10 is increased to about 80 to 100° C., for example, 90° C., and then, is decreased to room temperature so that the wavy trench lines 13 may be formed. Here, the temperature which the base substrate 10 reaches, the temperature increase speed, and the temperature decrease speed may be controlled to adjust the distances between the trench lines 13, and sizes and heights of the peaks and valleys in the waves of the trench lines 13.

Referring to FIGS. 1 and 2C, a mixture of the polymer-metal precursor is filled into the trench lines 13 of the base substrate 10 to form polymer-metal precursor mixture patterns 21 (S130). The composition for the stretchable conductive pattern is, for example, spin-coated on the base substrate 10 so as to fill the polymer-metal precursor mixture into the trench lines 13 of the base substrate 10. The solvent in the composition may be removed during the spin-coating operation.

In the polymer-metal precursor mixture, a polymer that may form a gel type by being cured by heat or light may be used. For example, the polymer may be PEG-DA, PS-PEO-PS, or POB-PEO; however, the embodiment of the present invention is not limited thereto.

As the metal precursor, a precursor of a metal having high conductivity such as Ag, Au, Pt, or Cu may be used. For example, AgCF₃COOH, AgNO₃, HAuCl₄, CuCl₂, PtCl₂, or PtCl₄ may be used as the metal precursor; however, the embodiment of the present invention is not limited thereto.

Referring to FIGS. 1 and 2D, polymer gel/metal nano-particle complex patterns 21′ are formed from the polymer-metal precursor mixture patterns 21 (S140).

In the polymer-metal precursor mixture, the polymer is cured to be in a gel type state and the metal precursor is reduced to the metal to form the polymer gel/metal nano-particle complex.

The polymer in the mixture may be cured by irradiating an ultraviolet (UV) ray irradiation or performing a heat treatment, or sequentially performing the UV irradiation and the heat treatment to be transformed to be in the gel type state.

The reduction of the metal precursor may be performed by using a reducing agent. For example, the polymer-metal precursor mixture may be exposed to steam of hydrazine (N₂H₄) or may be processed by sodium borohydride (NaBH₄) so that the metal precursor in the polymer-metal precursor mixture may be reduced to the metal nano-particles.

On the other hand, the heat treatment may be performed after performing the UV irradiation and reducing the metal precursor.

Referring to FIGS. 1 and 2E, the polymer gel/metal nano-particle complex patterns 21′ are transferred on an acceptor substrate 31 to form the polymer gel/metal nano-particle complex patterns 21′ on the acceptor substrate 31 (S150).

The acceptor substrate 31 may be formed of a polymer material, for example, the same material as that of the first polymer substrate 11. Otherwise, the acceptor substrate 31 may be formed of another material besides the polymer.

First, a surface of the acceptor substrate 31 is processed to make the surface easily receive the polymer gel/metal nano-particle complex patterns 21′. Through the surface treatment of the acceptor substrate 31, a layer having functional groups which form a chemical bond with the acceptor substrate 31 and can form a cross-linkage on the exposed surface with the polymer gal/metal nano-particle complex patterns 21′ may be formed on the surface of the acceptor substrate 31. For example, if the surface of the acceptor substrate 31 is treated by 3-(trichlorosilyl)propyl methacrylate in a case where the acceptor substrate 31 is formed of PDMS, the cross-linkage is formed between the surface of the acceptor substrate 31 and the polymer gal/metal nano-particle complex patterns 21′ when the UV is irradiated so that the polymer gel/metal nano-particle complex patterns 21′ may be transferred onto the acceptor substrate 31.

In addition, the base substrate 10 on which the polymer gel/metal nano-particle complex patterns 21′ are formed is aligned and adhered to the acceptor substrate 31, and then the UV ray is irradiated to form the cross-linkage between the polymer gel/metal nano-particle complex patterns 21′ and the acceptor substrate 31 and transfer the polymer gel/metal nano-particle complex patterns 21′ onto the acceptor substrate 31.

On the other hand, the polymer gel/metal nano-particle complex patterns 21′ extending in a first direction are transferred onto the acceptor substrate 31, and after that, the polymer gel/metal nano-particle complex patterns 21′ extending in a second direction are secondarily transferred onto the acceptor substrate 31, and thus, the polymer gel/metal nano-particle complex pattern (not shown) that is a net type may be formed on the acceptor substrate 31.

The polymer gel/metal nano-particle complex pattern 21′ transferred on the acceptor substrate 31 may form a conductive electrode that may be stretchable. In addition, the polymer gel/metal nano-particle complex pattern 21′ forms a net to form a two-dimensional (2D) electrode. In addition, when a transparent polymer is used, the polymer gel/metal nano-particle complex patterns 21′ transferred onto the acceptor substrate 31 may be used as a transparent electrode.

The flexibility of the polymer gel/metal nano-particle complex pattern may be increased due to synergy of the flexibility of the polymer itself, the flexibility caused by a percolation network of the metal nano-particles in the polymer and the flexibility generated by the wavy patterns. Therefore, a stretchable range of the polymer gel/metal nano-particle complex pattern may be significantly increased while maintaining the conductivity.

The polymer gel/metal nano-particle complex pattern may be used in a flexible display, smart clothing, a dielectric elastomer actuator (DEA), a biocompatible electrode, and an electronic device used to detect electrical signals in a living body.

An electronic device including the stretchable electrode according to another embodiment of the present invention will be described as follows.

The electronic device includes a flexible substrate, and a plurality of stretchable electrodes formed as wave lines including polymer gel/metal nano-particle complexes.

The plurality of stretchable electrodes formed as waves including the polymer gel/metal nano-particle complexes may be formed by the above described method of forming the conductive pattern according to the previous embodiment. That is, a plurality of wavy trench lines are formed in a substrate, and the polymer gel/metal nano-particle complex patterns are formed in the trench lines and then the patterns are transferred onto a flexible substrate. Accordingly, the stretchable electrodes may be formed on the flexible substrate.

The polymer gel/metal nano-particle complex may include the polymer gel and metal nano-particles forming a percolation network in the polymer gel. The polymer gel may be formed of PEG-DA, PS-PEO-PS, or POB-PEO. The metal nano-particles may include, but are not limited to, Ag, Au, Cu, or Pt.

The stretchable electrodes may be formed as a plurality of wavy lines extending in a first direction and have the same phases as each other. Alternatively, the stretchable electrodes may include a plurality of first wavy lines extending in the first direction and a plurality of second wavy lines extending in a second direction. For example, the stretchable electrodes may be a combination of the plurality of wavy lines extending in an X-axis direction and a plurality of wavy lines extending in a Y-axis direction. On the other hand, the stretchable electrode may include a plurality of groups of plural wavy lines. Each group may include a plurality of wavy lines, and wavy lines in the same group may extend in the same direction, and wavy lines in the different groups may extend in the same or different directions. The wavy lines in one group may be in the form of wave, S-shape, or round sawtooth, and the wavy lines in other group(s) may have same or different intervals between peaks and/or same or different heights of peaks and valleys from the wavy lines of the other groups. The wave, S-shape or rounded sawtooth shape trenches may be formed using other known methods for forming trenches in a film.

The flexible substrate may be formed of a flexible polymer. On the other hand, the flexible substrate may include a circuit electrically connected to the electrodes.

The electronic device including the stretchable electrode formed on the flexible substrate may be applied to any field in which an electronic device needs to be flexible.

### EXAMPLES

In the Examples, a base substrate which was formed by coating a polystyrene (PS) layer having a thickness of about 50 to 200 nm on a PDMS base substrate having a thickness of 1 mm is used as an exemplary base substrate. In the following exemplary explanations and FIGS. the term “base substrate” (“10” in FIG. 2) and the term “PDMS” are interchangeably used. The base substrate was stretched and released in the X-axis direction and stretched and released in the Y-axis direction to form wrinkles that are repeatedly arranged at constant intervals on the base substrate. The wrinkles formed trench lines having regular waves that extend in the X-axis direction and have peaks and valleys in the Y-axis direction. On the other hand, in another embodiment of the present invention, the base substrate was stretched and released simultaneously in the X-axis and Y-axis directions, and thus, wrinkles irregularly arranged on the base substrate were formed. The wrinkles formed trench lines having waves extending in irregular directions and having peaks and valleys.

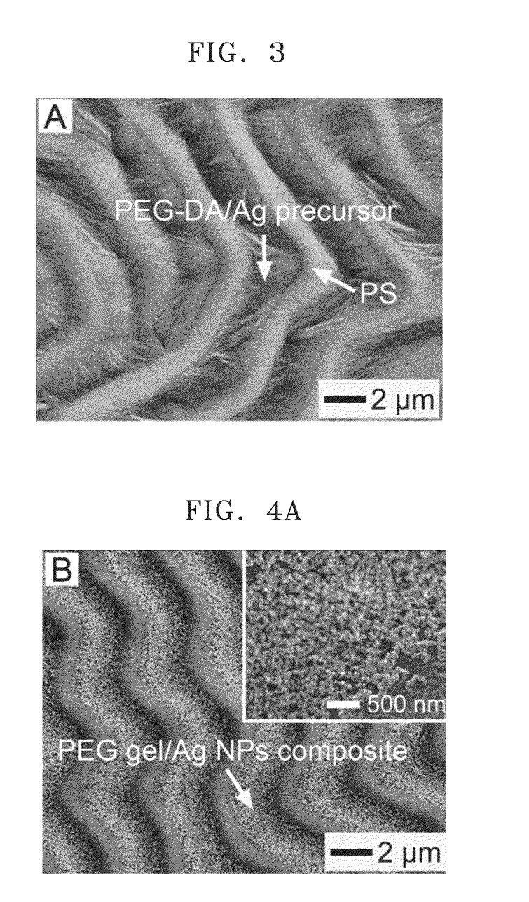

A mixture solution including PEG-DA polymer, AgCF₃COOH, and water was spin-coated on the base substrate to fill the mixture of PEG-DA polymer/AgCF₃COOH in the trench lines. FIG. 3 is a scanning electron microscopy (SEM) photograph showing the PEG-DA/Ag precursor mixture filled in the trench lines on the base substrate, in which the PS layer is formed on the PDMS base substrate.

Next, UV rays were irradiated onto the base substrate for 10 seconds to cure the PEG-DA polymer, and the base substrate was exposed to hydrazine (N₂H₄) vapor for 3 minutes in order to reduce the Ag precursor to Ag nano-particles and form a PEG-DA gel/Ag nano-particle complex pattern.

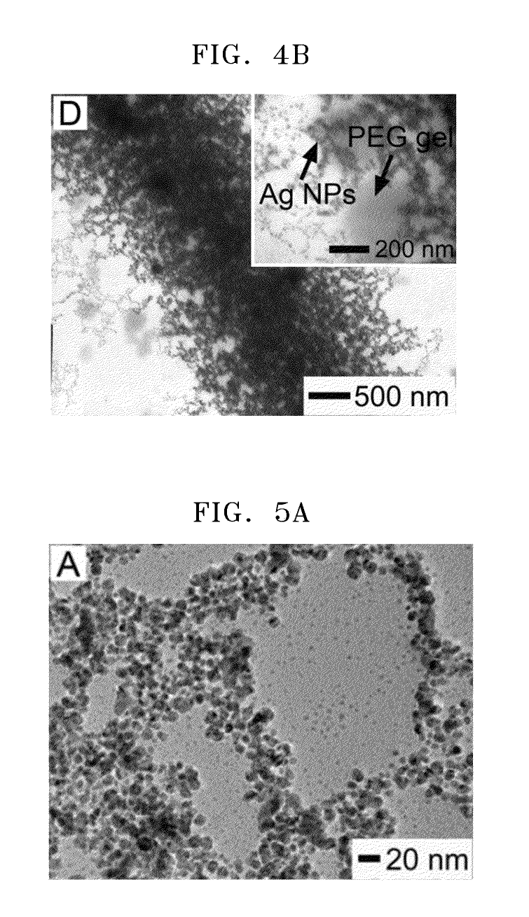

FIG. 4A is a SEM photograph showing the PEG-DA gel/Ag nano-particle complex pattern filled in the trench lines of the base substrate, and FIG. 4B is a transmission electron microscopy (TEM) photograph showing the PEG-DA gel/Ag nano-particle complex pattern of FIG. 4A. In the TEM photograph of FIG. 4B, a large amount of Ag nano-particles exist on a surface of the PEG-DA gel/Ag nano-particle complex pattern.

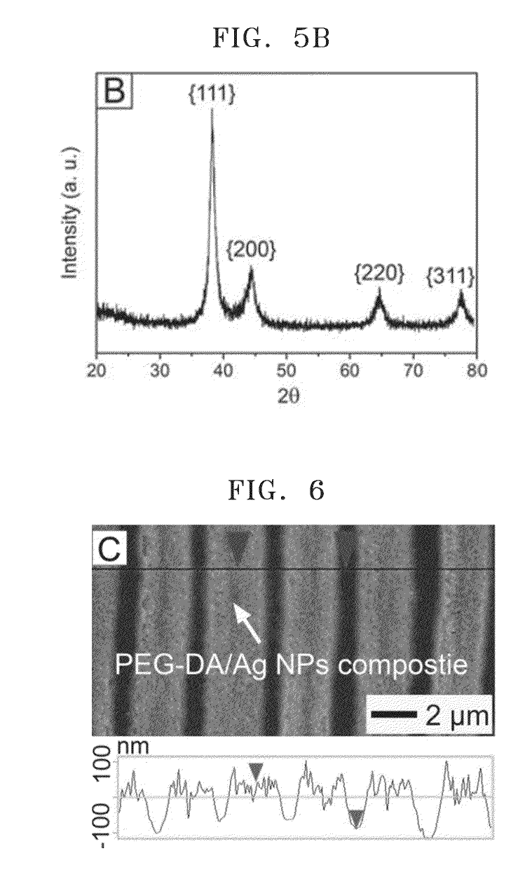

FIGS. 5A and 5B are respectively a TEM photograph and an X-ray diffraction (XRD) pattern showing the Ag nano-particles reduced from AgCF₃COOH. According to the TEM photograph of FIG. 5A, the Ag nano-particle has a diameter of about 10 to 20 nm, and according to the XRD pattern of FIG. 5B, the Ag nano-particle has a face-centered cubic structure.

Next, a surface of an acceptor substrate formed of PDMS was treated by using 3-(trichlorosilyl)propyl methacrylate, and after that, the base substrate was aligned and adhered to the acceptor substrate and UV rays were irradiated onto the base substrate so that the PEG-DA gel/Ag nano-particle complex patterns in the base substrate may be transferred onto the acceptor substrate.

FIG. 6 is an atomic force microscopy (AFM) image showing the PEG-DA gel/Ag nano-particle complex patterns transferred onto the acceptor substrate. In the AFM image of FIG. 6, a step having a thickness about 230 nm between patterns is shown, and thus, it is identified that the PEG-DA gel/Ag nano-particle (NP) complex patterns are transferred onto to the acceptor substrate.

FIG. 7 is a graph showing results of measuring the wt % of Ag in the PEG-DA gel/Ag nano-particle complex according to the concentration of AgCF₃COOH in a mixture solution of PEG-DA polymer and AgCF₃COOH. In the graph of FIG. 7, the wt % of the Ag in the PEG-DA gel/Ag nano-particle complex is increased greatly from about 10 wt % to about 65 wt % while the concentration of AgCF₃COOH increases from 0.25 wt % to about 2 wt %. After that, while the concentration of AgCF₃COOH increases to about 3 wt %, the wt % of the Ag is slowly increased to about 75%. Thus, as the concentration of AgCF₃COOH in the PEG-DA/AgCF₃COOH mixture solution increases, the wt % of the Ag in the PEG-DA gel/Ag nano-particle complex is saturated.

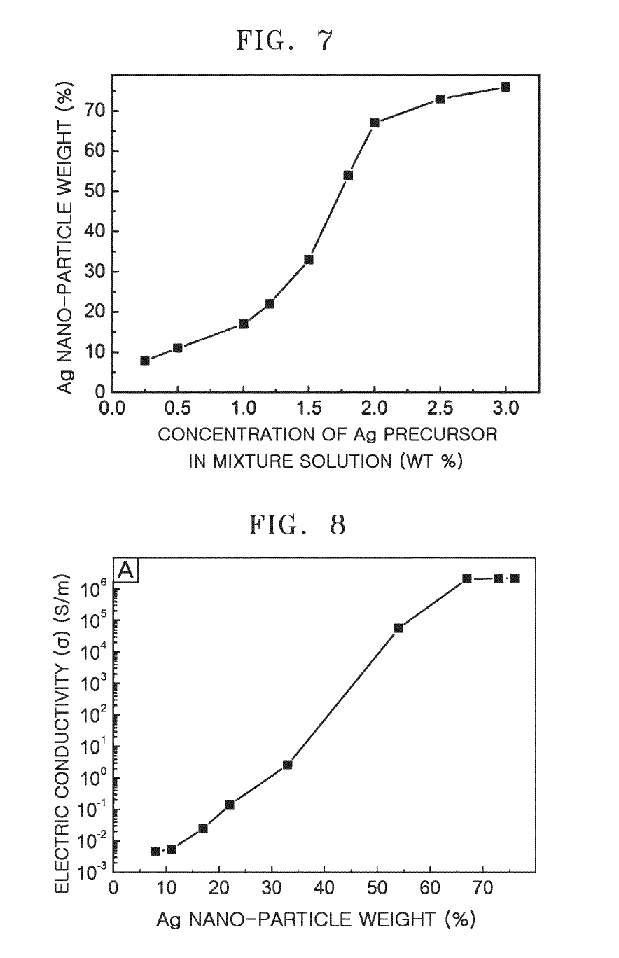

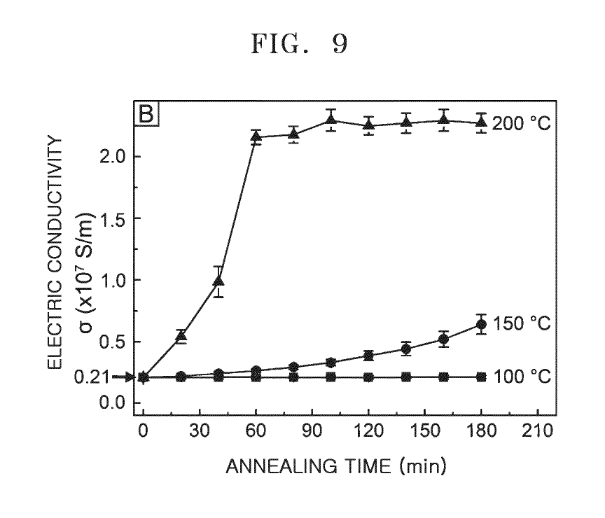

FIG. 8 is a graph measuring an electric conductivity of the PEG-DA gel/Ag nano-particle complex according to the wt % of the Ag nano-particle in the PEG-DA gel/Ag nano-particle complex. In the graph of FIG. 8, when the Ag is about 10 wt %, the electric conductivity is very low, that is, approximately 4.6×10-3 S/m; however, when the Ag is about 67 wt % or greater, an electric conductivity is constantly maintained at a high level, about 106 S/m. It is considered that the electric conductivity is saturated at a predetermined wt % of Ag or greater because the percolation network is formed between the Ag nano-particles.

FIG. 9 is a graph showing the electric conductivity of the PEG-DA gel/Ag nano-particle complex according to a temperature and a time taken to perform a heat treatment. The PEG-DA gel/Ag nano-particle complex was formed by performing the heat treatment after irradiating the UV rays for 10 seconds and performing a hydrazine (N₂H₄) reduction process for 3 minutes.

When the temperature of the heat treatment is 100° C., the electric conductivity is not increased according to the increase of the heat treatment time. When the temperature of the heat treatment is 150° C., the electric conductivity is increased from about 0.21×10⁷ S/m to about 0.6×10⁷ S/m according to the increase of the heat treatment time. When the temperature of the heat treatment is 200° C., the electric conductivity is sharply increased from about 0.21×10⁷ S/m to about 2.25×10⁷ S/m that is similar to the electric conductivity of an Ag thin film according to the increase of the heat treatment time. Therefore, it is considered that the percolation network between the Ag nano-particles is converted into a thin film state due to sintering occurred to the Ag nano-particles as the heat treatment duration increases when the temperature of the heat treatment is 200° C.

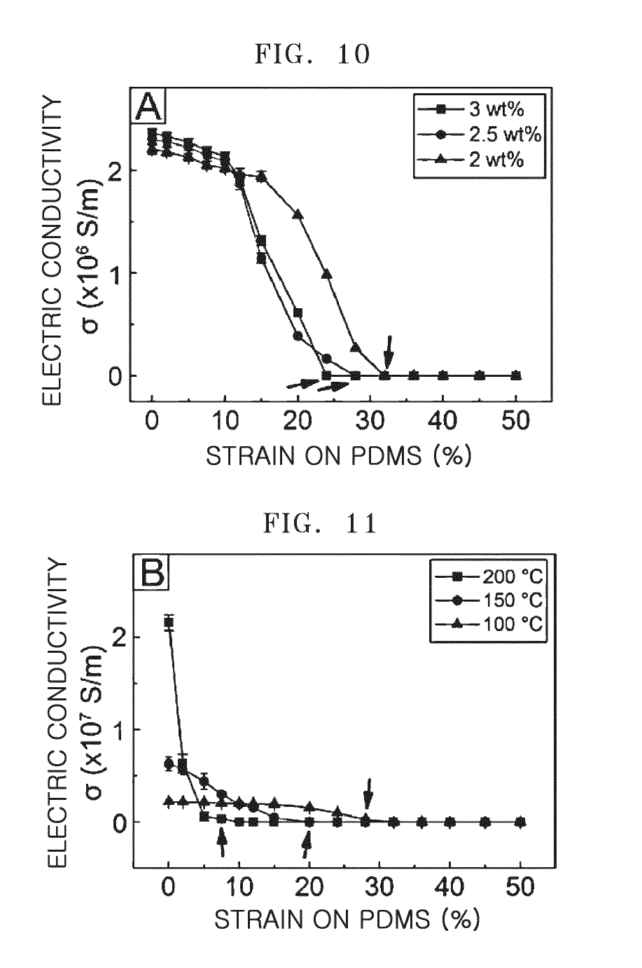

FIG. 10 is a graph showing a variation in the electric conductivity of the PEG-DA gel/Ag nano-particle complex which varies depending on the strain of the PDMS acceptor substrate according to a concentration of the Ag precursor. In the graph of FIG. 10, when the concentration of the Ag precursor is 2 wt % initially in the PEG-DA/Ag mixture solution, the electric conductivity is rapidly reduced at an strain degree of about 15% and reduced to 0 at an strain degree of about 32%. However, when the concentration of Ag is 2.5 and 3 wt % initially in the PEG-DA/Ag mixture solution, the electric conductivity starts to reduce rapidly at a strain degree of about 10% and is reduced to 0 at an strain degree of about 24% and about 28%. Therefore, when the amount of Ag precursor is increased in the PEG-DA/Ag mixture solution, there is an increase in the electric conductivity before the strain; however, a degree of strain (%) at which the mechanical breakdown occurs due to the strain is reduced. From the graphs of FIGS. 7, 8, and 10, it is considered that the electric conductivity of the PEG-DA/Ag nano-particle complex pattern is meaningful before and after the strain when the amount of Ag precursor ranges from about 1.5 to 3% or from about 1.5 to 2.5% in the PEG-DA/AgCF₃COOH mixture solution.

FIG. 11 is a graph showing a variation in the electric conductivity of the PEG-DA gel/Ag nano-particle complex pattern caused by the strain on the PDMS acceptor substrate, measured at various heat treatment temperature. After irradiating the UV rays for 10 seconds and performing the hydrazine (N₂H₄) reduction process for 3 minutes, heat treatments are performed for three hours at temperatures of 100° C., 150° C., and 200° C. In the graph of FIG. 11, the electric conductivities before applying strain to PDMS are high in an order of temperatures 200° C. (highest), 150° C., and 100° C. (lowest). However, the degree of strain (%) at which the electric conductivity was reduced to 0 was about 30% strain, when the heat treatment temperature was 100° C., about 20% when the heat treatment temperature was 150° , and about 10% when the heat treatment temperature was 200° C. Thus, the electric conductivities after the strain are high in the order of temperatures 100° C., 150° C., and 200° C. Therefore, the electric conductivity of the PEG-DA gel/Ag nano-particle complex pattern is significant before and after the strain when the temperature of the heat treatment is 150° C. or less or 100° or less.

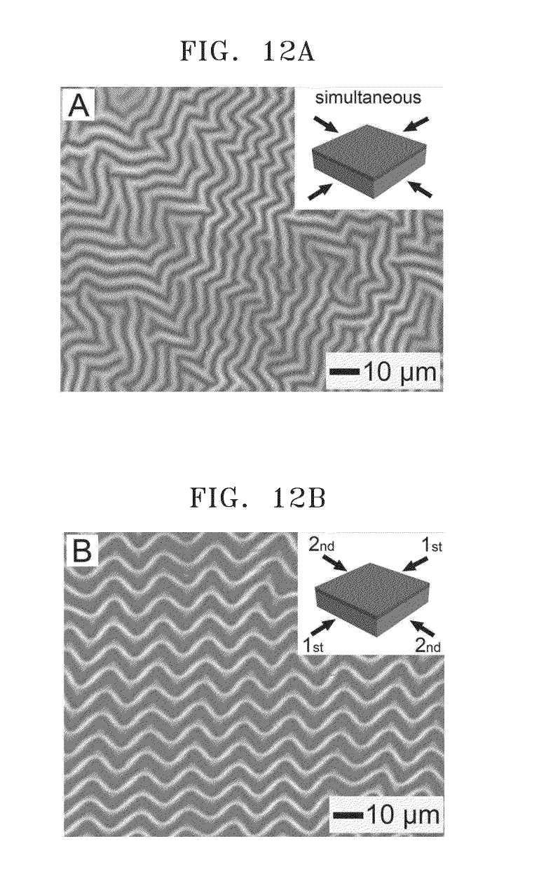

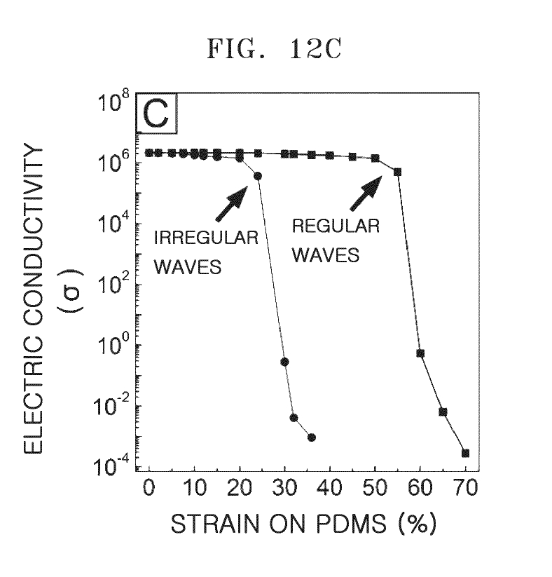

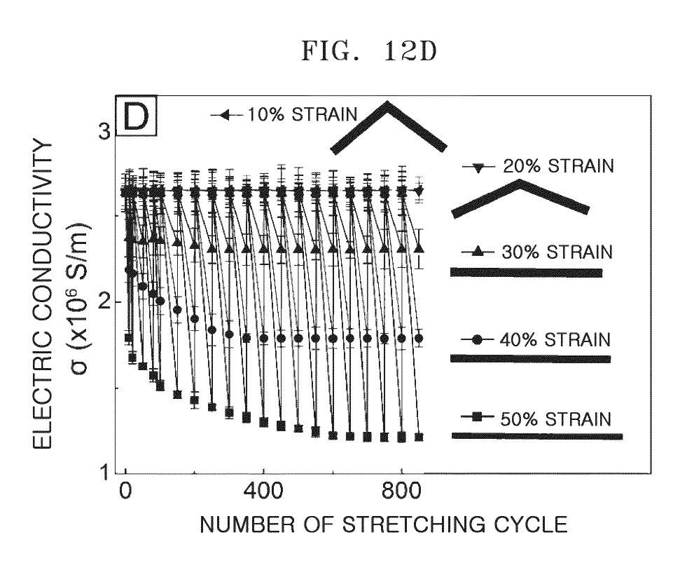

FIG. 12A is a SEM photograph of PEG-DA gel/Ag nano-particle complex patterns formed as irregular waves, and FIG. 12B is a SEM photograph of PEG-DA gel/Ag nano-particle complex patterns formed as regular waves. In each of the PEG-DA gel/Ag nano-particle complex patterns, the Ag nano-particles are 50 wt %. The irregular wave type PEG-DA gel/Ag nano-particle complex pattern shown in FIG. 12A were formed by stretching the PDMS base substrate and simultaneously releasing the PDMS in the first and second directions that are perpendicular to each other. The regular wave type PEG-DA gel/Ag nano-particle complex patterns shown in FIG. 12B were formed by stretching the PDMS in the first and second directions and sequentially releasing the PDMS in the first and second directions.

FIG. 12C is a graph of electric conductivities according to the strain applied to PDMS with an irregular wave type PEG-DA gel/Ag nano-particle complex pattern and to PDMS with a regular wave type PEG-DA gel/Ag nano-particle complex pattern. In the graph of FIG. 12C, in the irregular wave patterns, the electric conductivity starts to drop at the degree of strain of about 20%, and is reduced to 1 S/m or less at the degree of strain of about 30%. In the regular wave patterns, the electric conductivity starts to drop at the degree of strain of about 50%, and is reduced to 1 S/m or less at the degree of strain of about 60%. Thus, the electric conductivity according to the strain of the regular wave type PEG-DA gel/Ag nano-particle complex patterns is much higher than that of the irregular wave type PEG-DA gel/Ag nano-particle complex patterns. However, since irregular wave type PEG-DA gel/Ag nano-particle complex patterns also maintain the electric conductivity constantly within a predetermined range when the PDMS is strained, the irregular wave type PEG-DA gel/Ag nano-particle complex patterns may be also used to form the stretchable conductive patterns.

FIG. 12D is a graph of electric conductivity according to an stretch cycles of pattern of the regular wave type PEG-DA gel/Al nano-particle complex pattern measured at various degrees of strain. In the PEG-DA gel/Ag nano-particle complex pattern of FIG. 12D, the Ag nano-particles are 67 wt % with respect to the entire complex pattern (100 wt %), and the heat treatment is not performed after irradiating the UV rays. The electric conductivity is measured at the degrees of strain of 10%, 20%, 30%, 40%, and 50%. In the graph of FIG. 12D, the electric conductivity is further reduced during the strain as the degree of extension (%) increases, and the reduction of the electric conductivity according to the number of the stretching cycles becomes greater as the degree of extension (%) increases. In the graph of FIG. 12D, the electric conductivity of the PEG-DA gel/Ag nano-particle complex pattern is maintained constantly at 1×10⁶ S/m or greater with respect to the repeated stretching operations at the degree of extension of 50%.

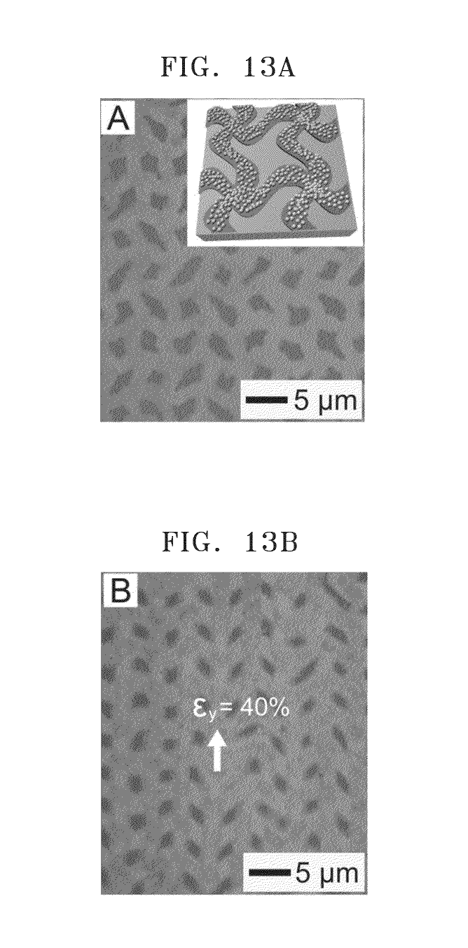

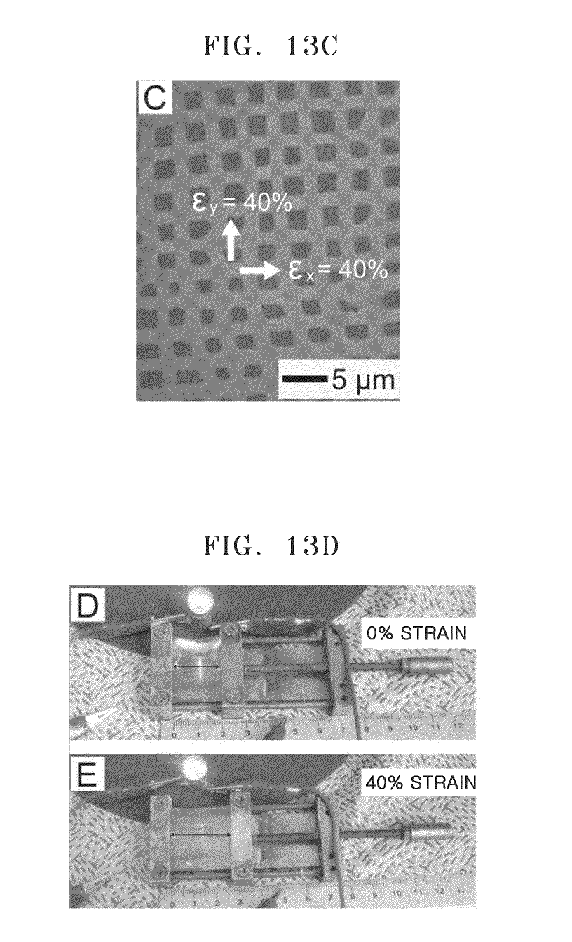

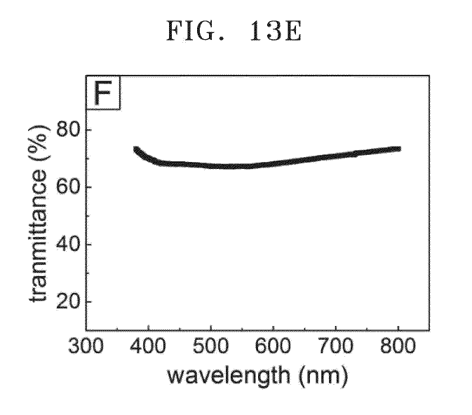

FIG. 13A is an optical microscope photograph showing a regular net type conductive pattern that is formed by transferring the regular wave type PEG-DA gel/Ag nano-particle complex patterns extending in the first direction on the acceptor substrate, and then transferring the regular wave type PEG-DA gel/Ag nano-particle complex patterns extending in the second direction that is perpendicular to the first direction on the acceptor substrate. FIG. 13B is a photograph showing the acceptor substrate, on which the regular net type conductive patterns are transferred, strained in the first direction by about 40%, and FIG. 13C is a photograph showing the acceptor substrate, on which the regular net type conductive patterns are transferred, strained in the first and second directions by about 40%. In FIGS. 13B and 13C, the net type conductive patterns are maintained after the strain of the acceptor substrate by about 40%.

FIG. 13D is a photograph showing connecting states of circuits before and after strain of the stretchable electrode in a bulb circuit using the conductive pattern of FIG. 13A as the stretchable electrode. An upper image of FIG. 13D shows that the bulb is turned on before strain the stretchable electrode, and a lower image of FIG. 13D shows that the bulb is turned on when the stretchable electrode is strain by 40%. From the photographs of FIG. 13D, the electric conductivity of the stretchable electrode is maintained even when the stretchable electrode is extended in a direction by 40%.

FIG. 13E is a graph of a transmittance of the PDMS on which the net type conductive patterns are formed. In the graph of FIG. 13E, the transmittance is maintained at about 70% on UV ray/visible ray regions. The transmittance of the pattern may be adjusted by changing the interval between the wave type patterns and the width of the wave. Therefore, the PEG-DA gel/Ag nano-particle complex patterns may be used as the transparent electrode.

Since the metal nano-particles form the percolation network in the stretchable polymer and the pattern has the waves which can be bended and stretched, the flexibility of the pattern may be improved and the high electric conductivity may be maintained when stretching the pattern. Therefore, the pattern may be used in the stretchable electrode.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A composition for forming a stretchable conductive pattern, the composition comprising:
a polymer which forms a gel by a photocuring or a thermal curing;
a metal precursor; and
a solvent.

2. The composition of claim 1, wherein the polymer include polyethyleneglycol diacrylate, polystyrene polyethyleneoxide polystyrene, or polyoxybutylene polyethyleneoxide.

3. The composition of claim 1, wherein the weight % (wt %) of the polymer is about 0.1 to about 10 wt % based on the total mass of the composition.

4. The composition of claim 1, wherein the metal precursor comprises AgCF₃COOH, AgNO₃, HAuCl₄, CuCl₂, PtCl₂, or PtCl₄.

5. The composition of claim 1, wherein the wt % of the metal precursor is about 0.1 to about 10 wt % based on the total mass of the composition.

6. The composition of claim 1, wherein the solvent includes water, ethanol, dimethylformamide, or dimethyl sulfoxide.

7. A method of forming a stretchable conductive pattern, the method comprising:
forming a base substrate;
forming a plurality of wavy trench lines that have peaks and valleys arranged at constant intervals in the base substrate;
forming a polymer-metal precursor mixture pattern by filling the trench lines with a mixture of a polymer and a metal precursor;
converting the polymer-metal precursor mixture of the polymer-metal precursor mixture pattern into a polymer gel/metal nano-particle complex to form a polymer gel/metal nano-particle complex pattern; and
primarily transferring the polymer gel/metal nano-particle complex pattern in the base substrate onto an acceptor substrate.

8. The method of claim 7, wherein the forming of the base substrate comprises:
providing a first polymer substrate that has elasticity and may be transformed by heat or stretching; and
forming a first polymer layer that may be transformed by heat or stretching and has a different elastic modulus or a different thermal expansion coefficient from the material forming the first polymer substrate, on the first polymer substrate.

9. The method of claim 7, wherein the non-linear trench lines are in a form of wave or S-shape, and wherein the forming of the plurality of wavy trench lines on the base substrate comprises stretching and releasing the base substrate in a first direction and stretching and releasing the base substrate in a second direction that is perpendicular to the first direction.

10. The method of claim 7, wherein the plurality of wavy trench lines are arranged at an equal distance between each trench line.

11. The method of claim 10, wherein the trench lines are extended in a first direction, the peaks of each trench line are parallel with the peaks of an adjacent trench line, and the valleys of each trench line are parallel with the valleys of an adjacent trench line.

12. The method of claim 7, wherein the forming of the plurality of wavy trench lines in the base substrate comprises raising a temperature of the base substrate to about 80 to about 100° C. and returning the temperature to room temperature.

13. The method of claim 7, wherein the filling of the trench lines with the polymer-metal precursor mixture comprises coating a polymer-metal precursor composition including a polymer which forms a gel by a photocuring or a thermal curing, a metal precursor, and a solvent on the base substrate in which the trench lines are formed.

14. The method of claim 7, wherein a polymer in the polymer-metal precursor mixture include polyethyleneglycol diacrylate, polystyrene polyethyleneoxide polystyrene, or polyoxybutylene polyethyleneoxide.

15. The method of claim 7, wherein the metal precursor comprises AgCF₃COOH, AgNO₃, HAuCl₄, CuCl₂, PtCl₂, or PtCl₄.

16. The method of claim 7, wherein the converting of the polymer-metal precursor mixture into a polymer gel/metal nano-particle complex comprises:
curing a polymer in the polymer-metal precursor mixture into a gel state; and
reducing a metal precursor of the polymer-metal precursor mixture.

17. The method of claim 16, wherein the reducing of the metal precursor comprises processing the polymer-metal precursor mixture in hydrazine or sodium borohydride.

18. The method of claim 16, wherein the curing of the polymer into the gel state comprises irradiating UV rays or performing a heat treatment on the polymer-metal precursor mixture.

19. The method of claim 7, wherein the transferring of the polymer gel/metal nano-particle complex pattern comprises performing a surface treatment on the acceptor substrate so as to obtain a UV-curable surface which can have a cross-linkage with the polymer gel/metal nano-particle complex before the transferring of the polymer gel/metal nano-particle complex pattern.

20. The method of claim 7, wherein the transferring of the polymer gel/metal nano-particle complex pattern comprises:
aligning the base substrate on which the polymer gel/metal nano-particle complex pattern is formed on the acceptor substrate; and
adhering the base substrate aligned on the acceptor substrate to the acceptor substrate, and irradiating UV rays on the base substrate to form cross-linkages between the polymer gel/metal nano-particle complex pattern and the acceptor substrate.

21. The method of claim 7, comprising primarily transferring the polymer gel/metal nano-particle complex pattern on the acceptor substrate, and secondarily transferring the polymer gel/metal nano-particle complex pattern on the acceptor substrate, wherein a direction of the polymer gel/metal nano-particle complex pattern transferred primarily is different from a direction of the polymer gel/metal nano-particle complex pattern transferred secondarily.

22. An electronic device comprising:
a flexible substrate; and
a stretchable electrode formed of a polymer gel/metal nano-particle complex and disposed on the flexible substrate, said stretchable electrode including a plurality of wavy lines.

23. The electronic device of claim 22, wherein the polymer gel/metal nano-particle complex includes a polymer gel and metal nano-particles forming a percolated network in the polymer gel.

24. The electronic device of claim 22, wherein the polymer gel in the polymer gel/metal nano-particle complex includes polyethyleneglycol diacrylate, polystyrene polyethyleneoxide polystyrene, or polyoxybutylene polyethyleneoxide.

25. The electronic device of claim 22, wherein the metal nano-particle of the polymer gel/metal nano-particle complex comprises Ag, Au, Cu, or Pt.

26. The electronic device of claim 22, wherein the plurality of wave lines extend in a first direction, and the waves have the same phases as each other.

27. The electronic device of claim 22, wherein the plurality of wavy lines form a plurality of groups of wavy lines, and wherein the plurality of wavy lines in the same group extend in the same direction, and the plurality of wavy lines in another groups extend in the same to or different direction from the plurality of wavy lines in other groups.

28. The electronic device of claim 22, wherein the plurality of wavy lines form a network including a plurality of first wavy lines extending in a first direction and a plurality of second wave lines extending in a second direction.

29. The electronic device of claim 22, wherein the flexible substrate is formed of a flexible polymer.

30. The electronic device of claim 22, wherein the flexible substrate comprises a circuit electrically connected to the stretchable electrode.
